(19) United States
(12) Patent Application Publication
(10) Pub. No.: US 2012/0013700 A1
(43) Pub. Date: Jan. 19, 2012

(54) NOVEL FUSED POLYCYCLIC COMPOUND AND ORGANIC LIGHT-EMITTING DEVICE INCLUDING THE SAME

(75) Inventors: Takayuki Horiuchi, Tokyo (JP); Jun Kamatani, Tokyo (JP); Tetsuya Kosuge, Yokohama-shi (JP); Akihito Saitoh, Gotemba-shi (JP)

(73) Assignee: CANON KABUSHIKI KAISHA, Tokyo (JP)

(21) Appl. No.: 13/259,983

(22) PCT Filed: Mar. 29, 2010
(86) PCT No.: PCT/JP2010/002241

§ 371 Date: Sep. 23, 2011

(30) Foreign Application Priority Data
Apr. 8, 2009 (JP) 2009-094100

(51) Int. Cl. B41J 2/47; H01L 31/153; H01L 51/54

(52) U.S. Cl. 347/225; 257/40; 257/E51.024; 257/E31.102

(57) ABSTRACT

Provided is a fused polycyclic compound represented by general formula 1:

(In general formula 1, at least one of R₁ to R₄ is a group selected from a substituted or unsubstituted aryl group and a substituted or unsubstituted heterocyclic group, and R₁ to R₄ may be the same as or different from each other.)

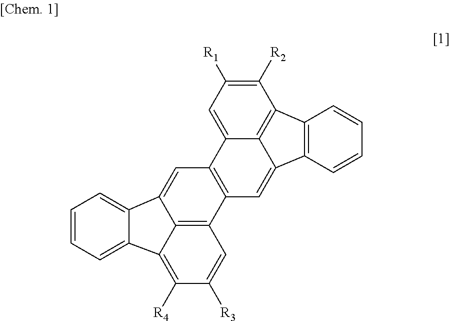

### TECHNICAL FIELD

The present invention relates to a novel fused polycyclic compound and an organic light-emitting device including the novel fused polycyclic compound.

### BACKGROUND ART

An organic light-emitting device is constituted by an anode, a cathode, and a thin-film containing a fluorescent organic compound interposed between the anode and the cathode. When electrons and holes are respectively injected from the electrodes, excitons of the fluorescent compound are generated and the organic light-emitting device emits light as the excitons return to their ground state. Recent advancement of organic light-emitting devices has been remarkable. The organic light-emitting devices feature that they can achieve a high luminance with low application voltage, a wider variation of emission wavelengths, and high-speed response, and enable thickness and weight reduction of light-emitting appliances. Thus the organic light-emitting devices suggest possibilities that they can be used in a wide variety of usages.

However, at the present, the luminance of the optical output must be increased and the conversion efficiency must be enhanced. Moreover, many problems associated with durability remain unresolved such as changes over time caused by long-term use and deterioration caused by oxygen-containing ambient gas and humidity.

In order for the organic light-emitting devices to be applicable to full color displays and the like, emission of blue light having high color purity must be achieved at a high efficiency. However, these challenges are not sufficiently addressed. Meanwhile, organic light-emitting devices that have particularly high color purity, emission efficiency, and durability and materials for realizing such devices are increasingly sought after.

In order to address these challenges, attempts have been made to use organic compounds having a fluoranthene or benzofluoranthene backbone in light-emitting devices (see Patent Literatures 1 and 2).

However, these organic compounds still need improvements in terms of emission hue, the emission efficiency, the luminance, and the durability.

There has also been a report of synthetic examples of organic compounds having a diindenochrysene backbone (Non Patent Literature 1).

### CITATION LIST

### Patent Literature

### PTL 1: WO2008-015945

### PTL 2: WO2008-059713

### Non Patent Literature

NPL 1: J. Org. Chem., 64, 1650-1656 (1999)

### SUMMARY OF INVENTION

The present invention provides a novel fused polycyclic compound and an organic light-emitting device that contains the novel fused polycyclic compound and exhibits highly pure emission hue, highly efficient and highly luminous optical output, and high durability.

An aspect of the present invention provides a fused polycyclic compound represented by general formula [1]:

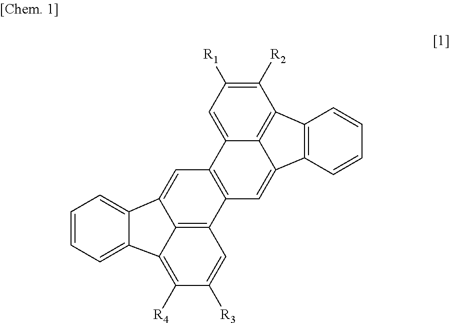

(In general formula [1], at least one of R₁ to R₄ is a group selected from a substituted or unsubstituted aryl group and a substituted or unsubstituted heterocyclic group, and R₁ to R₄ may be the same as or different from each other.)

According to the present invention, a novel fused polycyclic compound that exhibits highly pure emission hue and high stability and, in particular, that is represented by general formula [1] can be provided. The novel fused polycyclic compound can be used as a material for an organic light-emitting device. With this novel fused polycyclic compound, an organic light-emitting device that exhibits highly pure emission hue, highly efficient and highly luminous optical output, and high durability can be provided.

### BRIEF DESCRIPTION OF DRAWINGS

FIG. 1A is a schematic diagram showing an organic light-emitting device and a unit configured to supply electrical signals.

FIG. 1B is a schematic diagram showing a pixel circuit connected to a pixel, and signal and electrical current supply lines connected to the pixel circuit.

FIG. 2 is a diagram showing a pixel circuit.

FIG. 3 is a schematic cross-sectional view showing an organic light-emitting device and a thin film transistor underneath.

FIG. 4 shows a structural formula of Compound C-1, electron clouds of the highest occupied molecular orbital (HOMO), and electron clouds of the lowest un-occupied molecular orbital (LUMO).

### DESCRIPTION OF EMBODIMENTS

The present invention will now be described in details.

A novel fused polycyclic compound of the present invention is a fused polycyclic compound represented by general formula [1] below:

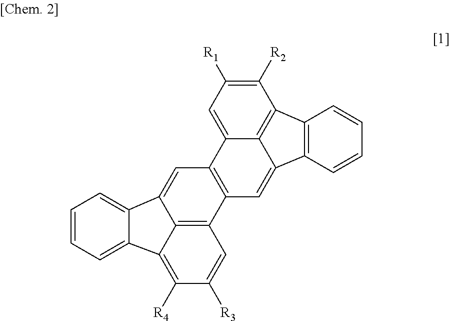

In general formula [1], at least one of R₁ to R₄ is a group selected from a substituted or unsubstituted aryl group and a substituted or unsubstituted heterocyclic group, and R₁ to R₄ may be the same as or different from each other.

The fused polycyclic compound represented by general formula [1] used in the present invention is a compound in which at least one substituted or unsubstituted aryl or heterocyclic group substitutes a particular position in a diindenochrysene backbone. Unsubstituted diindenochrysene has a fluorescent peak wavelength at 434 nm in a diluted solution, which is a fluorescent characteristic suitable for blue fluorescent materials, in particular, for light-emitting materials for organic light-emitting devices. However, since fused polycyclic compounds have planar structures, they are sparingly soluble in organic solvents and extremely difficult to synthesize or purify. Usually, such problems are avoided by introducing various types of substituents. The effects of the position and the type of the introduced substituents on the fluorescent characteristic and thermal stability of the diindenochrysene backbone are discussed in detail below.

First, the effect of the substitution position on the fluorescent wavelength is discussed. Second, the effect of suppressing intermolecular association brought about by introduction of aryl substituents is discussed. Thirdly, the type of substituents to be introduced is discussed.

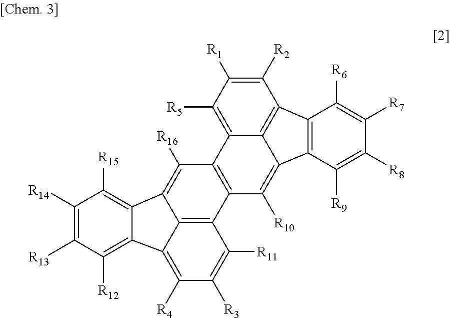

First, the effect of the substitution position on the fluorescent wavelength is discussed with reference to Table 1.

The fluorescent spectra of Example Compound 1-1 represented by general formula [1], C-1 (diindenochrysene), C-2, and C-3 in toluene diluted solutions were measured. C-1 is represented by general formula [2] with R₁ to R₁₅ each representing a hydrogen atom. C-2 is represented by general formula [2] with R₇ and R₁₃ each representing a 2-methyl-1-naphtyl group and all other Rs each representing a hydrogen atom. C-3 is represented by general formula [2] with R₆ and R₉ each representing a phenyl group, R₁₂ and R₁₅ each representing a 3,5-di-tert-butylphenyl group, and all other Rs each representing a hydrogen atom. As shown in Table 1 below, relative to the unsubstituted compound C-1, Example Compound 1-1 shows the smallest increase in wavelength among other compounds and also has good CIE chromaticity. These results show that Example Compound 1-1 emits fluorescent light closer to pure blue than C-2 and C-3 and is thus superior as the blue fluorescent material.

TABLE 1

| | | CIE | |
|---|---|---|---|
| | Fluorescent | chromaticity of | Difference in |
| | peak | fluorescent | peak wavelength |
| | wavelength | spectrum | from C-1 |
| | (nm) | (x, y) | (nm) |
| C-1 | 434 | (0.15, 0.11) | — |
| Example | 438 | (0.15, 0.12) | 4 |
| Compound 1-1 | | | |
| C-2 | 447 | (0.14, 0.16) | 13 |
| C-3 | 456 | (0.14, 0.19) | 22 |

The effects of the introduced substituents on the fluorescent spectra will now be discussed. Example Compound 1-1 and C-2 both have two aryl substituents but differ in fluorescent peak wavelength by as much as 9 nm from each other. The molecular orbital of diindenochrysene C-1 was calculated at the B3LYP/6-31G* level using a density functional theory.

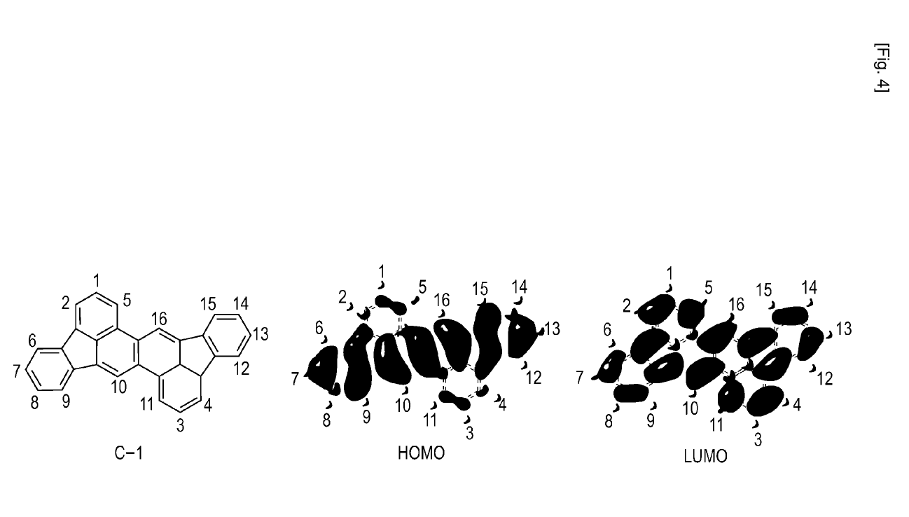

The electron clouds of the highest occupied molecular orbital (HOMO) and the electron clouds of the lowest unoccupied molecular orbital (LUMO) of compound C-1 are shown in FIG. 4. The numerical figures shown in the drawings indicate positions in the molecule.

The molecular orbital calculation shows that the electron clouds of the HOMO are distributed less on the carbon atoms bonded to R₁ to R₅ and R₁₁ and are mainly distributed on other carbon atoms in general formula [2]. The electron clouds of the LUMO are delocalized over the entire molecule and do not show significant polarization on the carbon atoms bonded to R₁ to R₁₆ in general formula [2]. Considering the calculation results and the results of the fluorescent spectrometry, it can be understand that, in a diindenochrysene backbone, the degree of perturbation relative to the HOMO differs depending on the positions of introducing the substituents and this difference leads to the difference in fluorescent characteristics.

The compound C-2 having aryl groups at R₇ and R₁₃ in general formula [2] contributes more to the resonance stabilization for the HOMO level than Example Compound 1-1 having aryl groups at R₁ and R₃ in general formula [1] and thus shows a larger increase in wavelength of the fluorescence than Example Compound 1-1. Moreover, in C-3, all of the four aryl groups occupy positions that easily perturb by the HOMO; hence, the effect of resonance stabilization worked strongly, resulting in the largest increase in wavelength.

Accordingly, in the cases where diindenochrysene derivatives are used as blue fluorescence materials, the positions where the substituents are to be introduced to suppress the increase in the wavelength of the fluorescence may be R₁ to R₅ and R₁₁ in general formula [2] above.

Second, the effect of suppressing intermolecular association brought about by introduction of aryl substituents is discussed.

Spin-coated films of Example Compound 1-1, C-1, C-2, and C-3 were fabricated and fluorescent spectra thereof were measured. Of these compounds, C-1 showed the largest shift in peak wavelength relative to that of the fluorescent spectrum in a diluted solution. The fluorescent spectrum observed was broad, extending across the green to yellow regions. This shows that in the unsubstituted compound, C-1, in a solid state, molecules are strongly associated with each other by the pi electron interactions on the fused rings, thereby achieving stabilization and the increase in wavelength of fluorescence.

The intermolecular association was suppressed most in C-3 having four aryl groups among the substituted indenochrysene derivatives. The comparison between Example Compound 1-1 and C-2 both having two aryl groups shows that the effect is higher when aryl groups are introduced to R₁ and R₃ in general formula [1] than when aryl groups are introduced to R₇ and R₁₃ in general formula [2].

Table 2 shows the peak wavelengths of the fluorescent spectra and CIE chromaticity of the spin-coated films and the difference in peak wavelength from that observed in toluene diluted solutions.

TABLE 2

| | | CIE | Difference in |
|---|---|---|---|
| | Fluorescent | chromaticity of | peak wavelength |
| | peak | fluorescent | from a toluene |
| | wavelength | spectrum | diluted solution |
| | (nm) | (x, y) | (nm) |
| C-1 | 508 | (0.27, 0.49) | 74 |
| Example | 489 | (0.16, 0.39) | 51 |
| Compound 1-1 | | | |
| C-2 | 510 | (0.26, 0.58) | 63 |
| C-3 | 481 | (0.17, 0.36) | 25 |

These results show that when diindenochrysene is used alone or mixed and dispersed in another material so that it can be used as a blue fluorescent material in a solid state, it is effective to introduce aryl substituents to suppress intermolecular association. Among the compounds from which spin-coated films are formed to measure the fluorescent spectra, Example Compound 1-1 and C-3 have fluorescence within the blue region even when they are formed into thin films alone. Moreover, Example Compound 1-1 can realize highly pure blue fluorescence when it is dispersed.

Thirdly, the type of substituents to be introduced is discussed.

NPL 1 describes a synthetic example of a diindenochrysene derivative, C-4 (compound represented by general formula [2] where R₁₀ and R₁₆ each represent a di(4-tert-butylphenyl)methyl group and all other R₅ each represent a hydrogen atom), and the thermal stability of C-4. For example, in J. Org. Chem., 64, 1650-1656 (1999), the text and Scheme 5 on pp. 1651-1652, and the section titled Chrysene 23 in Experimental Section in p. 1654, this synthetic example is described.

According to the description, when C-4 is heated in a sealed tube, C-4, which had initially been a yellow solid, gradually turns brown after 180 degrees (Celsius) and melts and decomposes at 332 degrees (Celsius). A methyl group bonded to diindenochrysene has a benzyl hydrogen. A radical and an anion pair generated by dissociation of the benzyl hydrogen take a resonance structure with the fused rings of the diindenochrysene, thereby achieving significant stabilization. Moreover, since the spa carbon bonded to the benzyl hydrogen is bonded to three aryl groups, the atoms are closely packed three-dimensionally and the structure is unstable. It can be assumed that due to such electronic and three-dimensional factors, the benzyl hydrogen in C-4 is highly unstable and thus easily causes pyrolysis. Such instability can lead to not only thermal instability but possibly also instability against oxygen, light, and bases. Thus, it is not preferable to use C-4 as the fluorescent material.

In contrast, Example Compound 1-1 was analyzed with a thermogravimetric/differential thermal analyzer (TG-DTA) in a nitrogen atmosphere but decomposition was not observed even at 380 degrees (Celsius). Example Compound 1-1 also has a benzyl hydrogen in a substituent, 2,4,6-triisopropylphenyl group. However, the carbon atom directly bonded to diindenochrysene is the sp² carbon in the aryl group and does not have a benzyl hydrogen. Thus, Example Compound 1-1 is more thermally stable than C-4. Thus, an aryl group and a heterocyclic group including sp² carbon may be the substituents to be introduced to diindenochrysene.

The three points can be summarized as below. Diindenochrysene derivatives useful as the blue fluorescent materials are fused polycyclic compounds represented by general formula [2] where at least one of R₁ to R₅ and R₁₁ is a group each independently selected from a substituted or unsubstituted aryl group and a substituted or unsubstituted heterocyclic group. However, the positions of R₅ and R₁₁ are respectively sterically hindered by R₁₆ and R₁₀ when the substituents are introduced through coupling reactions and the like, resulting in a decrease in yield and thus are not favored. This is notable even in cases where R₁₆ and R₁₀ are hydrogen atoms.

Therefore, the diindenochrysene derivative can be a fused polycyclic compound represented by general formula [1], where at least one of R₁ to R₄ is be a group selected from a substituted or unsubstituted aryl group and a substituted or unsubstituted heterocyclic group, and R₁ to R₄ may be the same as or different from each other.

In general formula [2], R₂ and R₄ are moderately sterically hindered by R₆ and R₁₂, respectively. The diindenochrysene derivative can also be a fused polycyclic compound represented by general formula [1], where R₂ and R₄ are each a hydrogen atom, at least one of R₁ and R₃ is a group selected from a substituted or unsubstituted aryl group and a substituted or unsubstituted heterocyclic group, and R₁ and R₃ may be the same as or different from each other.

The compound represented by general formula [1] used in the present invention is a fused polycyclic compound contained in an organic compound layer of an organic light-emitting device. This light-emitting device at least includes a pair of electrode and the organic compound layer interposed between the pair of electrode.

The pair of electrodes are an anode and a cathode. At least one of the anode and the cathode is transparent or semi-transparent (transmittance of about 50%) for the emission color.

The organic compound layer is the emission layer.

The “emission layer” refers to the very layer that emits light. The organic light-emitting device of the present invention may include other functional layers in addition to the emission layer. In such a case, the functional layers and the emission layer are laminated. The layer structure of the organic light-emitting device is described below.

The organic compound layer functioning as the emission layer contains a fused polycyclic compound represented by general formula [1].

The emission layer may use the fused polycyclic compound represented by general formula [1] alone or as a guest material.

For the purposes of the present invention, the “guest material” refers to a material that defines the substantial emission color of the organic light-emitting device and is the material that can itself emit light.

A “host material” refers to a material having a higher composition ratio than the guest material.

The guest material has a low composition ratio in the organic light-emitting layer and the host material has a high composition ratio in the organic light-emitting layer. Here, the “composition ratio” is indicated in terms of percent by weight with respect to all components constituting the organic compound layer as the denominator.

When the fused polycyclic compound represented by general formula [1] is used as the guest, the fused polycyclic compound content is preferably 0.1 wt % or more and 30 wt % or less with respect to the total weight of the emission layer. More preferably, the content is 0.1 wt % or more and 15 wt % or less to suppress concentration quenching. This numerical range also applies when the organic compound layer is composed of a host material and a guest material only.

The guest material may be contained in the organic compound layer homogeneously over the entire organic compound layer or by having a concentration gradient. Alternatively, some regions of the organic compound layer may contain the guest material while other regions do not.

When the fused polycyclic compound represented by general formula [1] is used as the guest, the host material it not particularly limited. However, in order to provide an organic light-emitting device constituted by stable amorphous films, a fused polycyclic derivative can be used. In order to provide an organic light-emitting device exhibiting high efficiency and high durability, the emission yield of the host material itself must be high and the chemical stability of the host itself must be high. Thus, the host material may be a chemically stable fused polycyclic derivative that exhibits high fluorescent quantum yield, e.g., fluorene derivatives, pyrene derivatives, fluoranthene derivatives, and benzofluoranthene derivatives.

In order to provide an organic light-emitting device having high durability, the compounds constituting the organic light-emitting device must be chemically stable.

The fused polycyclic compound represented by general formula [1] is characterized in that because of the electron-withdrawing effect of the five-membered ring structures, the reactivity for the electrophilic reaction with singlet oxygen molecules or the like is low and the compound is thus chemically stable. Moreover, since there are two five-membered ring structures, the compound shows higher chemical stability than those having a backbone with one five-membered ring, such as fluoranthene and benzofluoranthene.

The fused polycyclic compound represented by general formula [1] has electron injectability because of the electron-withdrawing property of the five-membered ring structures and can decrease the driving voltage when used as the material for the organic light-emitting device. Moreover, since there are two five-membered ring structures, the compound shows a higher effect of decreasing the driving voltage than those having a backbone with one five-membered ring, such as fluoranthene and benzofluoranthene.

When the organic light-emitting device of the present invention is applied to a display, the organic light-emitting device can be used as a blue light-emitting pixel within the display region of the display. The fused polycyclic compound represented by general formula [1] has an emission peak at 430 to 440 nm in a diluted solution, which is the optimum position for the peak.

In general, when organic light-emitting devices are used in displays, it is important that the emission peaks of the blue light-emitting materials of the blue light-emitting devices be in the range of 430 to 480 nm

In other words, the organic light-emitting device of the present invention not only contains a blue light-emitting material having an emission peak in a range desirable for providing a blue light-emitting device. The organic light-emitting device of the present invention contains a blue light-emitting material having an emission peak in a range of 430 to 440 nm, which is narrower than the range of 430 to 480 nm

The organic compound for the organic light-emitting device may be a material having a molecular weight of 1000 or less. This is because sublimation purification can be used as the purification technique. Sublimation purification is highly effective for increasing the purity of the material.

The organic compound contained in the organic compound layer of the organic light-emitting device of the present invention can be a fused polycyclic compound represented by general formula [1] above having a molecular weight of 1000 or less.

The fused polycyclic compound represented by general formula [1] contained in the organic compound layer of the organic light-emitting device of the present invention is favored for its thermal stability.

In forming the organic compound layer of the organic light-emitting device, the organic compound undergoes steps such as sublimation purification and vapor deposition.

In such a case, the organic compound is subject to a temperature of 300 degrees (Celsius) or higher under high vacuum of about 10⁻³ Pa. If the material has low thermal stability, decompositions and reactions would occur and the desired physical properties may not be obtained.

Examples of the substituents (R₁ to R₄) of the fused polycyclic compound represented by general formula [1] are as follows.

Examples of the substituted or unsubstituted aryl groups include, but are not limited to, a phenyl group, a naphthyl group, an indenyl group, a biphenyl group, a terphenyl group, and a fluorenyl group.

Examples of the substituted or unsubstituted heterocyclic groups include, but are not limited to, a pyridyl group, an oxazolyl group, an oxadiazolyl group, a thiazolyl group, a thiadiazolyl group, a carbazolyl group, an acridinyl group, and a phenanthrolyl group.

Examples of the substituent that may be included in the above-described substituents, i.e., the aryl group and the heterocyclic group, include, but are not limited to, alkyl groups such as a methyl group, an ethyl group, and a propyl group; aralkyl groups such as a benzyl group; aryl groups such as a phenyl group and a biphenyl group; heterocyclic groups such as a pyridyl group and a pyrrolyl group; amino groups such as a dimethylamino group, a diethylamino group, a dibenzylamino group, a diphenylamino group, and a ditolylamino group; alkoxy groups such as a methoxy group, an ethoxy group, a propoxy group, and a phenoxy group; a cyano group; and halogen atoms such as fluorine, chlorine, bromine, and iodine atoms.

Specific examples of the fused polycyclic compound represented by general formula [1] used in the present invention include, but are not limited to, follows:

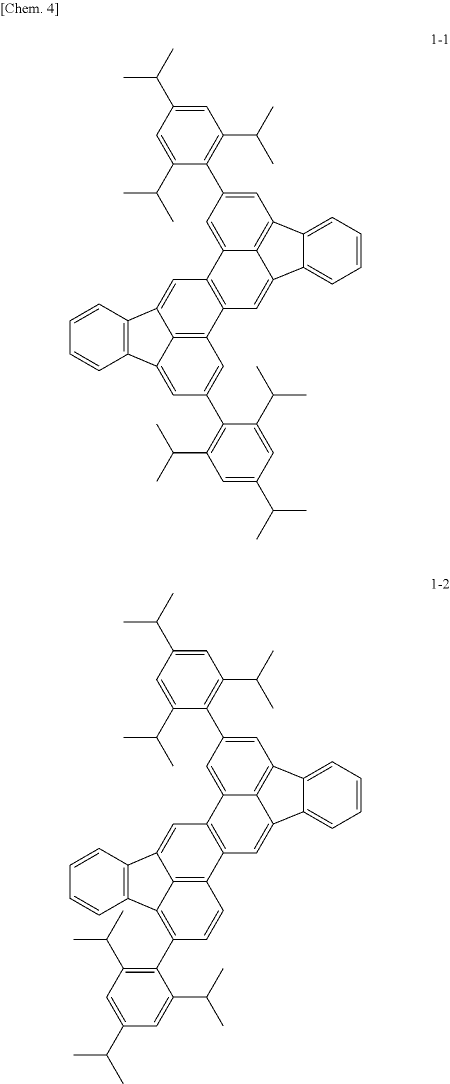

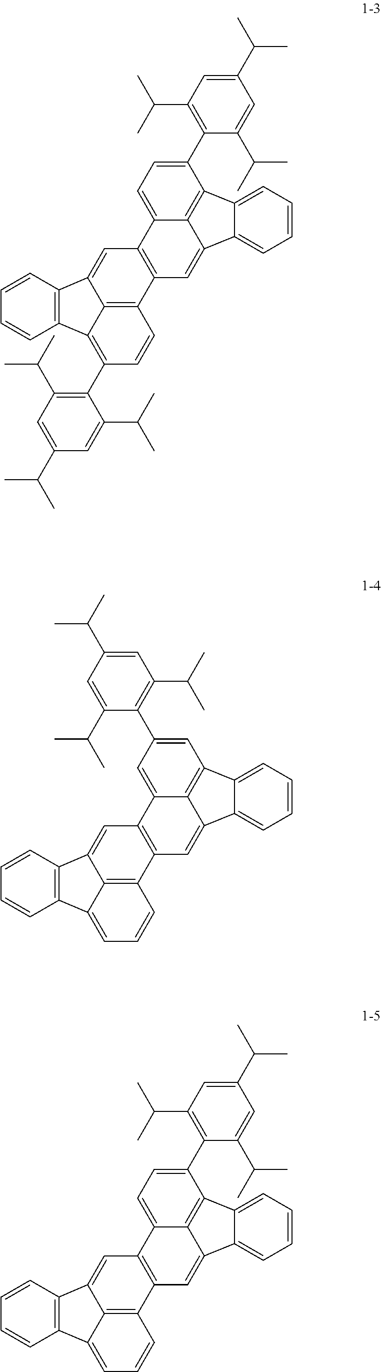

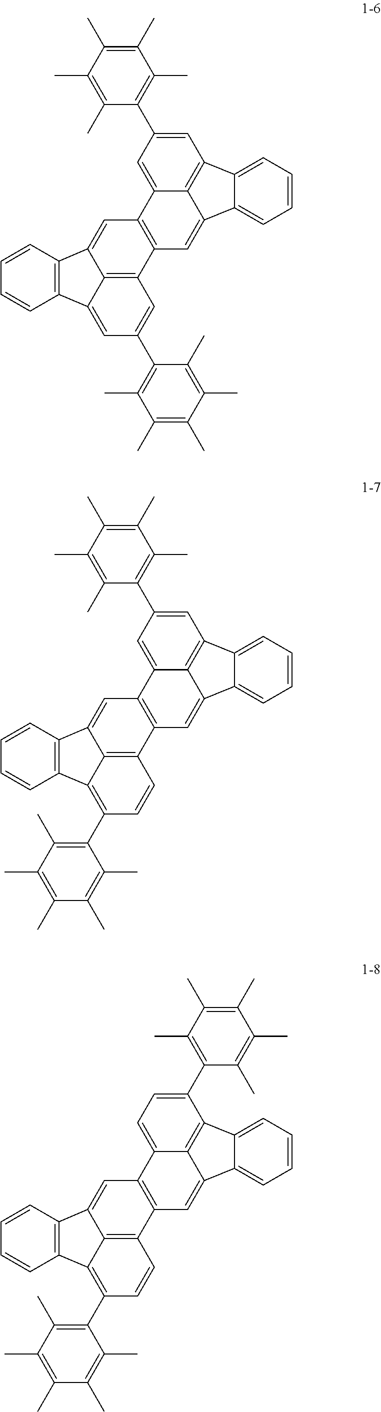

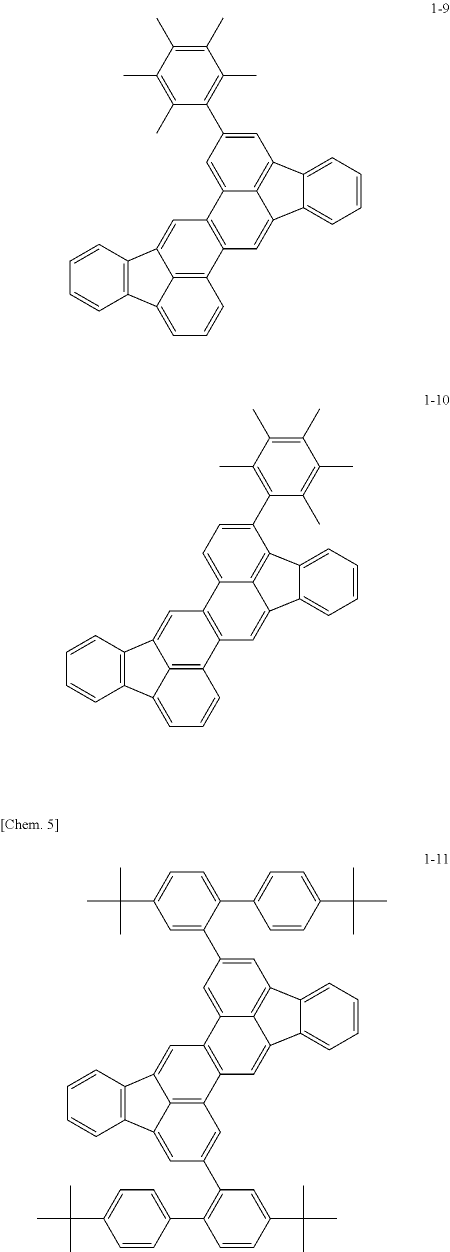

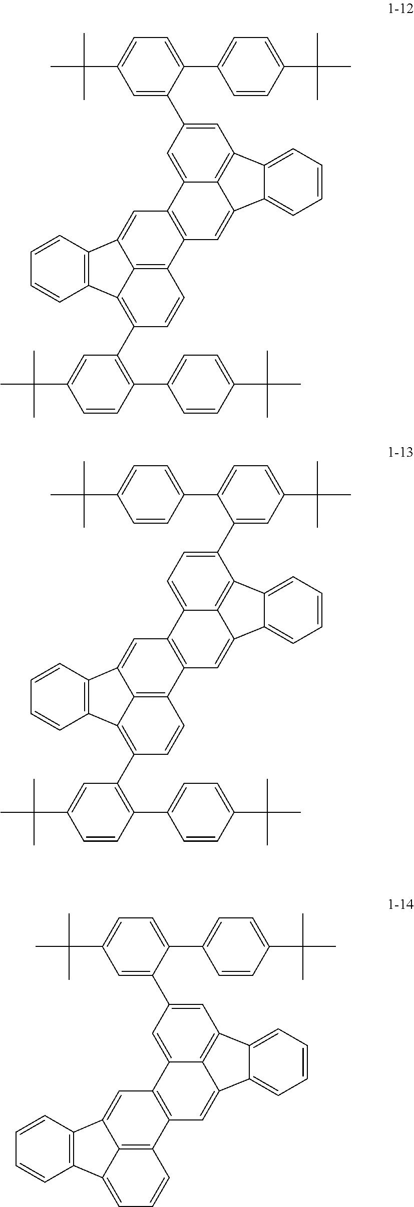

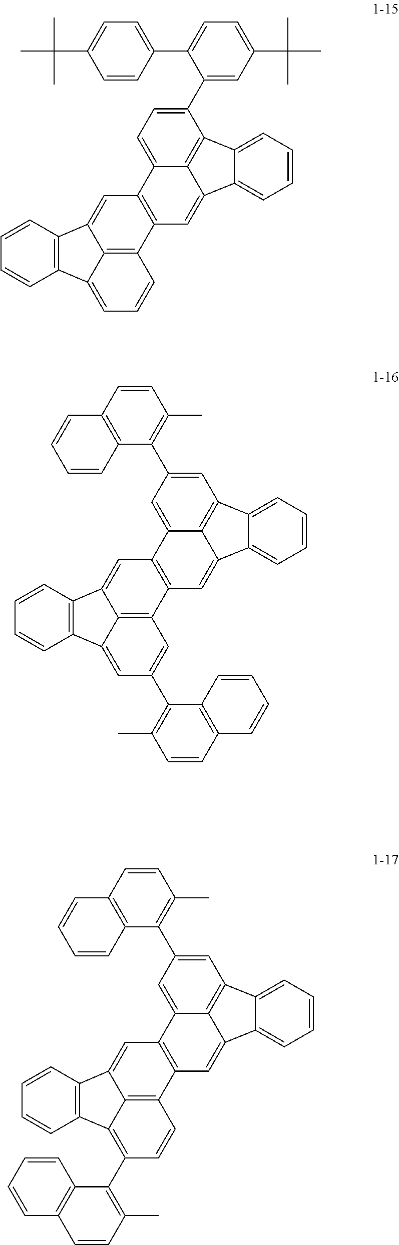

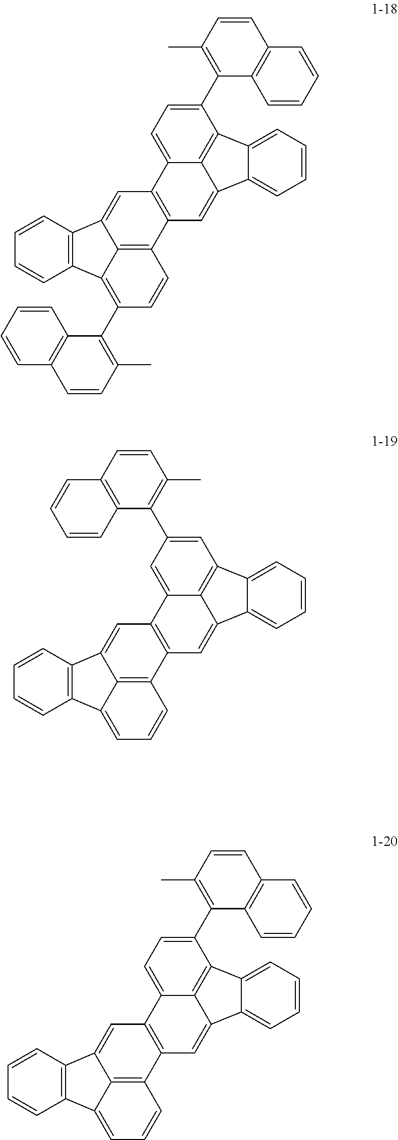

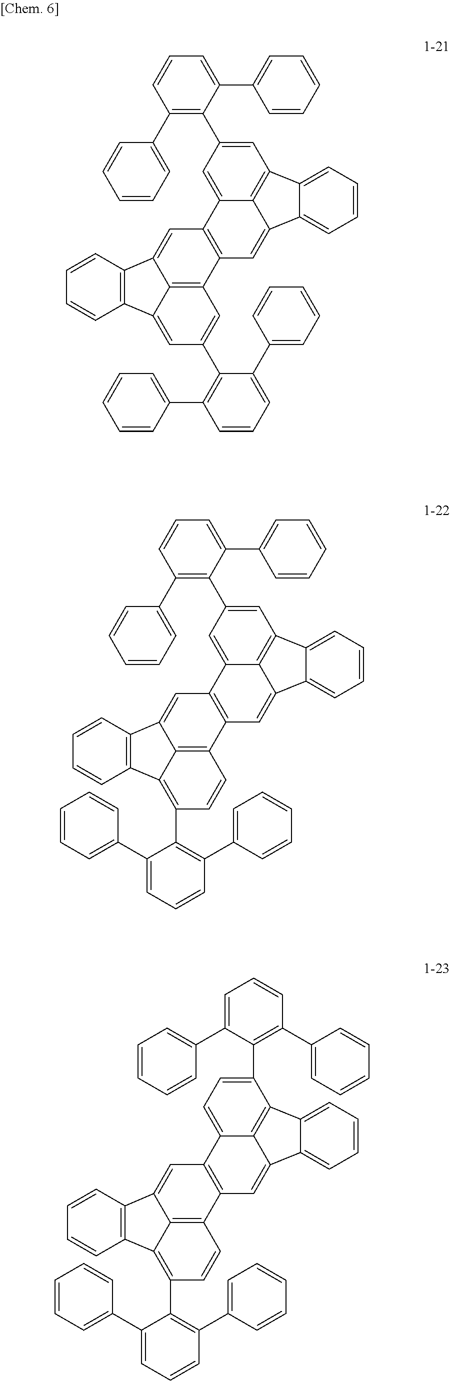

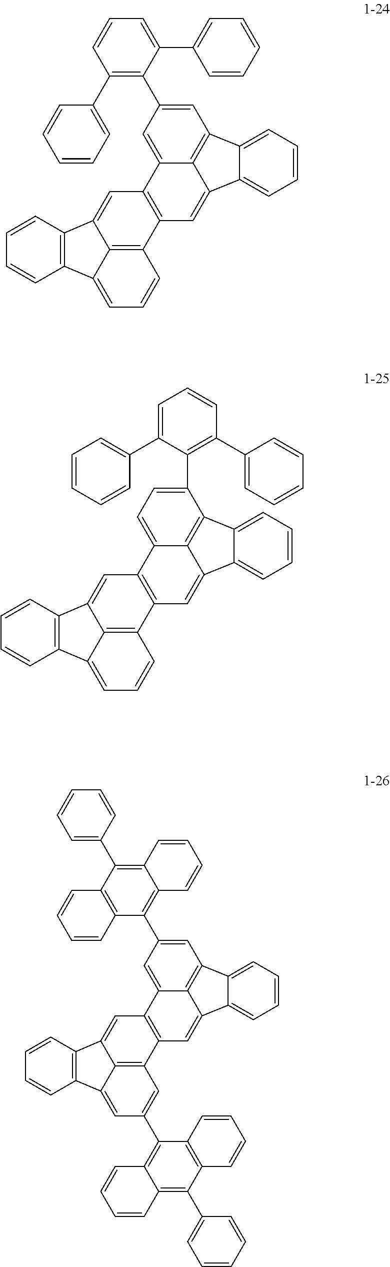

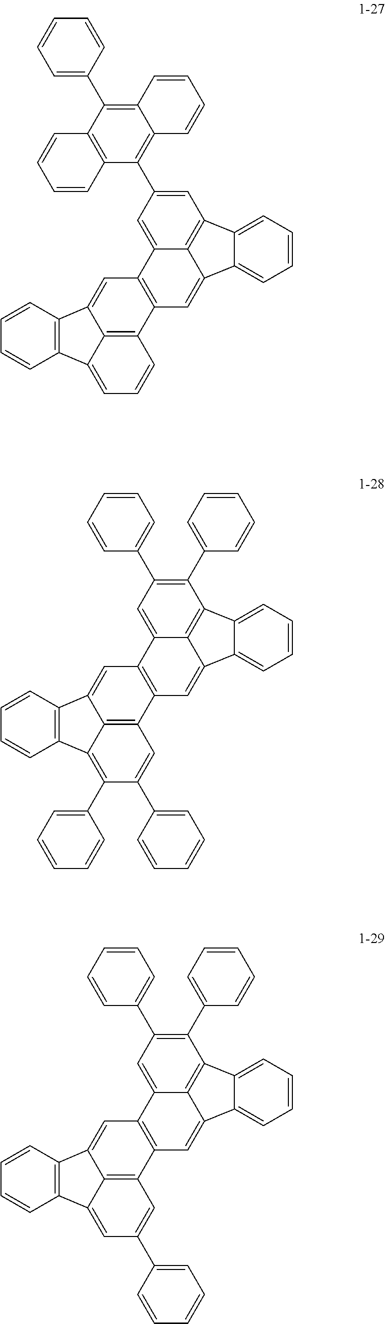

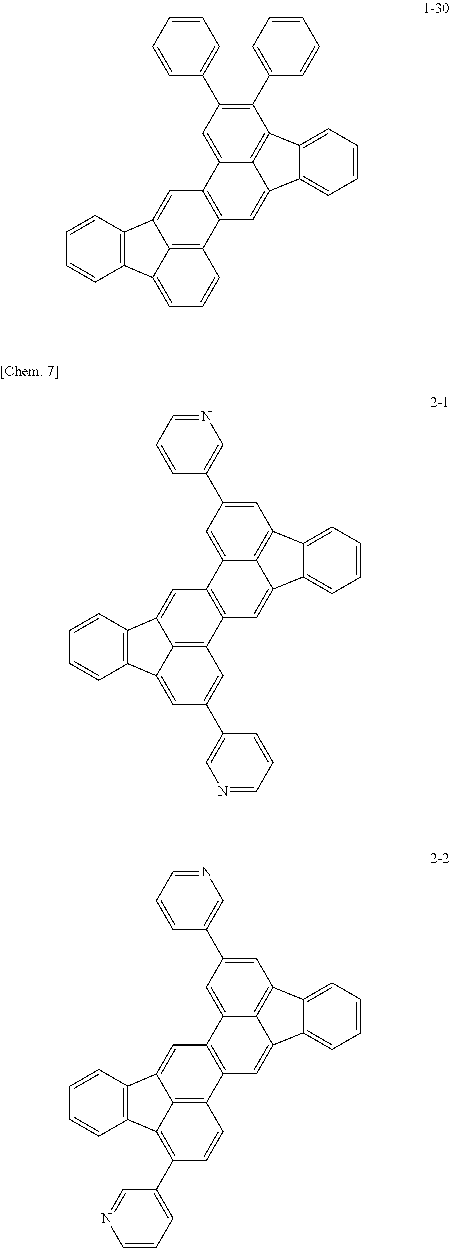

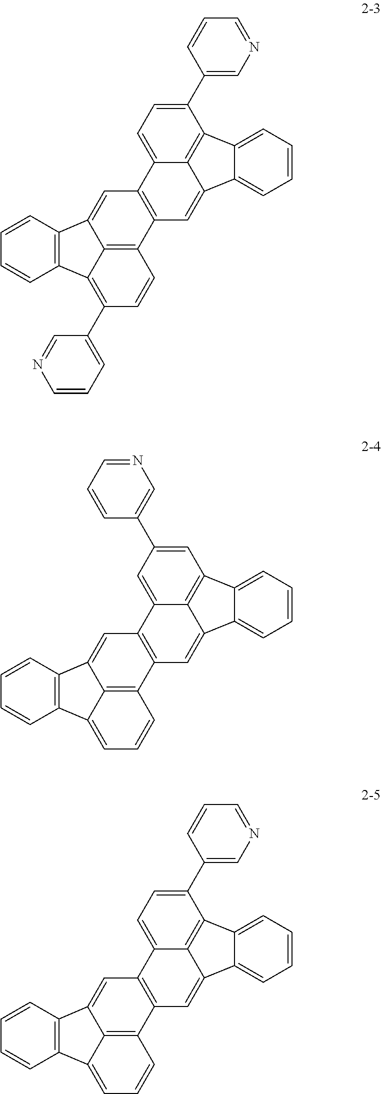

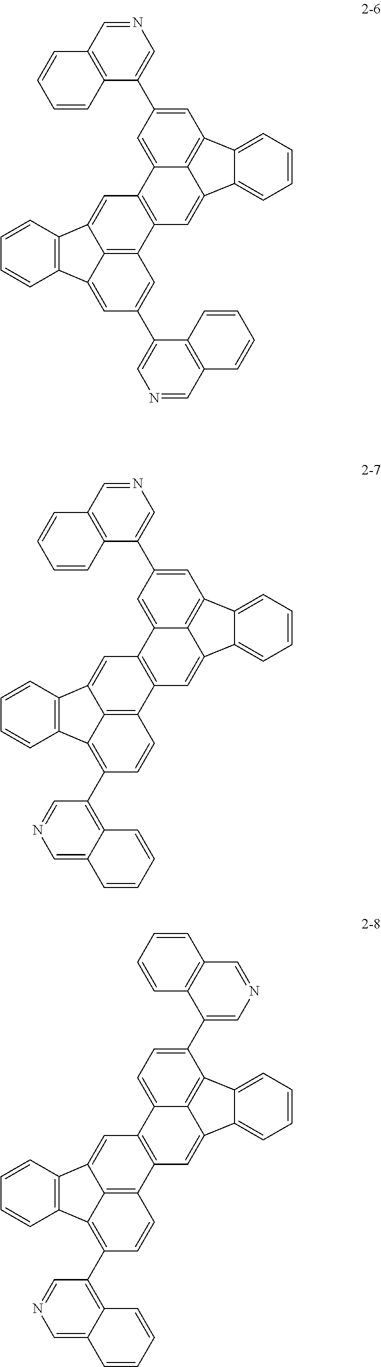

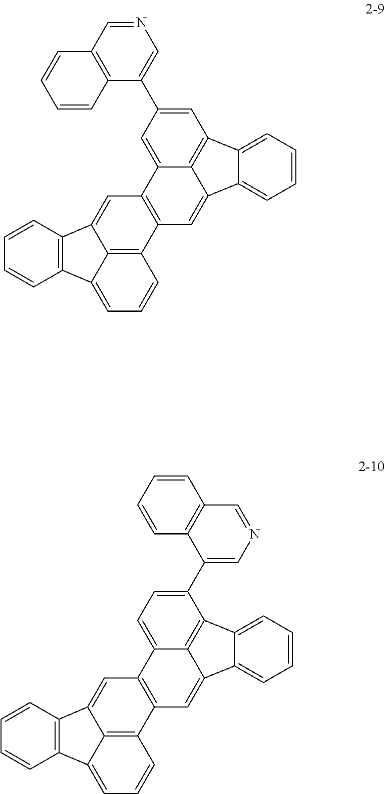

First to fifth examples of the multilayer organic light-emitting devices are as follows.

A first example of a multilayer organic light-emitting device is a structure in which an anode, an emission layer, and a cathode are sequentially layered on a substrate. This type of organic light-emitting device is useful when the emission layer itself has all of the hole transport property, the electron transport property, and the light-emitting property or when compounds having respective properties are mixed and used in the emission layer.

A second example a multilayer organic light-emitting device is a structure in which an anode, a hole transport layer, an electron transport layer, and a cathode are sequentially layered on a substrate. In this structure, the emission layer containing the guest material is either the hole transport layer or the electron transport layer.

A third example of a multilayer organic light-emitting device is a structure in which an anode, a hole transport layer, an emission layer, an electron transport layer, and a cathode are sequentially layered on a substrate. In this structure, the carrier transport function and the light-emitting function are separated. Compounds respectively having a hole transport property, an electron transport property, and a light-emitting property may be adequately combined and used in the device. This significantly increases the flexibility of choices of materials. Moreover, since various different compounds with different emission wavelengths can be used, the variety of the emission hue can be widened. Carriers or excitons can be effectively confined in the center emission layer to enhance the emission efficiency.

A fourth example a multilayer organic light-emitting device is a structure in which an anode, a hole injection layer, a hole transport layer, an emission layer, an electron transport layer, and a cathode are sequentially layered on a substrate. This structure improves the adhesiveness between the anode and the hole transport layer and improves the hole injectability, which is effective for decreasing the voltage.

A fifth example of a multilayer organic light-emitting device is a structure in which an anode, a hole transport layer, an emission layer, a hole/exciton-blocking layer, an electron transport layer, and a cathode are sequentially layered on a substrate. In this structure, a layer (hole/exciton-blocking layer) that prevents holes or excitons from reaching the cathode is interposed between the emission layer and the electron transport layer. Since a compound having a significantly high ionization potential is used in the hole/exciton-blocking layer, the emission efficiency can be effectively enhanced.

The first to fifth examples of the multilayer devices are merely exemplary basic device structures and do not limit the structure of the organic light-emitting device of this invention. For example, various other layer structures can be employed such as providing an insulating layer at the interface between an electrode and an organic layer, providing an adhesive layer or an optical interference layer, designing the hole transport layer to be made up of two layers with different ionization potentials.

The organic compound layer of the organic light-emitting device of the present invention may contain a low-molecular-weight or polymer hole or electron transport compound in addition to the fused polycyclic compound represented by general formula [1] if needed.

Examples of the compound are as follows.

Hole injection/transport materials used in the hole injection layer and the hole transport layer may have a high hole mobility so that holes can be easily injected from the anode and the injected holes can be transferred to the emission layer.

Examples of the low-molecular-weight and polymer materials having hole injection/transport functions include, but are not limited to, triarylamine derivatives, phenylenediamine derivatives, triazole derivatives, oxadiazole derivatives, imidazole derivatives, pyrazoline derivatives, pyrazolone derivatives, oxazole derivatives, fluorenone derivatives, hydrazone derivatives, stilbene derivatives, phthalocyanine derivatives, porphyrin derivatives, poly(vinyl carbazole), polysilylene, polythiophene, and other electrically conductive polymers.

The hole injection/transport material used in the electron injection layer and/or electron transport layer can be adequately selected from those that allow easy injection of electrons from the cathode and transport the injected electrons to the emission layer. A material is selected by considering the balance with the carrier mobility of the hole transport material and the like. Examples of the material having the electron injection/transport function include, but are not limited to, oxadiazole derivatives, oxazole derivatives, thiazole derivatives, thiadiazole derivatives, pyrazine derivatives, triazole derivatives, triazine derivatives, perylene derivatives, quinoline derivatives, quinoxaline derivatives, fluorenone derivatives, anthrone derivatives, phenanthroline derivatives, and organometal complexes.

The organic compound layer containing the fused polycyclic compound represented by general formula [1] of the present invention and layers composed of other organic compounds in the organic light-emitting device of the present invention are formed by the following methods: vacuum vapor deposition, ionization deposition, sputtering, plasma-enhanced deposition, and various existing coating techniques (e.g., spin-coating, dipping, casting, a Langmuir-Blodgett technique, and ink-jet) that involve dissolving the compounds in adequate solvents.

When layers are formed by vacuum vapor deposition or a solution coating technique, crystallization and other unfavorable phenomena rarely occur and stability with time is excellent. When a coating technique is used to form films, an adequate binder resin may be used in combination.

The binder resin may be selected from a wide range of binder resins. Examples of the binder resin include, but are not limited to, polyvinyl carbazole resin, polycarbonate resin, polyester resin, polyarylate resin, polystyrene resin, ABS resin, polybutadiene resin, polyurethane resin, acryl resin, methacryl resin, butyral resin, polyvinyl acetal resin, polyamide resin, polyimide resin, polyethylene resin, polyether sulfone resin, diallyl phthalate resin, phenol resin, epoxy resin, silicone resin, polysulfone resin, and urea resin.

These binder resins can be used alone as a homopolymer or in combination as a copolymer. If needed, additives such as a plasticizer, an antioxidant, and a UV absorber may be used in combination.

The anode material may be a material having a work function as high as possible. Examples of such a material include, but are not limited to, single metals such as gold, platinum, silver, copper, nickel, palladium, cobalt, selenium, vanadium, and tungsten, and their alloys; and metal oxides such as tin oxide, zinc oxide, indium oxide, indium tin oxide (ITO), and zinc indium oxide. Electrically conductive polymers such as polyaniline, polypyrrole, polythiophene, polyphenylene sulfide, and the like can also be used. These electrode substances may be used alone or in combination. The anode may have a single-layer structure or a multilayer structure.

In contrast, the cathode material may be a material having a small work function. Examples of such a material include single metals such as lithium, sodium, potassium, cesium, calcium, magnesium, aluminum, indium, ruthenium, titanium, manganese, yttrium, silver, lead, tin, and chromium; and alloys such as lithium-indium, sodium-potassium, magnesium-silver, aluminum-lithium, aluminum-magnesium, and magnesium-indium. Metal oxides such as indium tin oxide (ITO) can also be used. These electrode substances may be used alone or in combination. The cathode may have a single-layer structure or a multilayer structure.

The substrate used in the organic light-emitting device of the present invention is not particularly limited. For example, an opaque substrate such as a metal substrate or a ceramic substrate, or a transparent substrate such as a glass substrate, a quartz substrate, and a plastic sheet may be used. A color filter film, a fluorescence color conversion filter film, a dielectric reflective film, or the like may be formed on the substrate to control the color of emission.

A protective layer or a sealing layer may be provided to the fabricated device in order to prevent the device from contacting oxygen, moisture, and the like.

Examples of the protective layer include inorganic material films such as diamond thin films and metal oxide and metal nitride films; polymeric films of fluorocarbon resin, polyethylene, silicone resin, and polystyrene resin; and films of photocurable resin. The device may be covered with glass, a gas-impermeable film, a metal, or the like and packaged with an adequate sealing resin.

As for the direction in which the light is output from the device, either a bottom-emission structure (light is output from the substrate side) or a top-emission structure (light is output from the side opposite the substrate) is applicable.

The organic light-emitting device of the present invention can be applied to products that require energy saving and high luminance Examples of the application include light sources of display apparatuses such as PC monitors and televisions, lighting apparatuses, and printers, and backlights for liquid crystal display apparatuses. The organic light-emitting device of the present invention may be used as a pixel in a finder, which is a display section, of an image-capturing apparatus including a lens, a photo detector, and the like, i.e., a digital still camera or a digital video camera.

When the organic light-emitting device is applied to a display apparatus, a high-visibility, light-weight, energy-saving flat panel display can be made.

As for the light source of printers, the organic light-emitting device of the present invention can replace the laser light source unit of widely used laser beam printers. Organic light-emitting devices that can be addressed independently may be arranged on an array, and an image (latent image) is formed by conducting exposure of the photosensitive drum. In such a case, the volume of the apparatus can be significantly reduced.

When the organic light-emitting device of the present invention is applied to lighting apparatuses and backlights, energy conservation can be achieved.

A color filter film, a fluorescence color conversion filter film, a dielectric reflective film, or the like may be formed on the substrate to control the color of emission.

A thin film transistor (TFT) may be formed on the substrate and the device can be made to connect to the TFT. It is also possible to form a matrix on a substrate to form a device and use the device for lighting.

Next, a display apparatus that uses the organic light-emitting device of the present invention is described. This display apparatus includes the organic light-emitting device of the present invention and a unit configured to supply electrical signals to the organic light-emitting device. The display apparatus of the present invention is described in detail below by taking an active matrix system as an example with reference to the drawings.

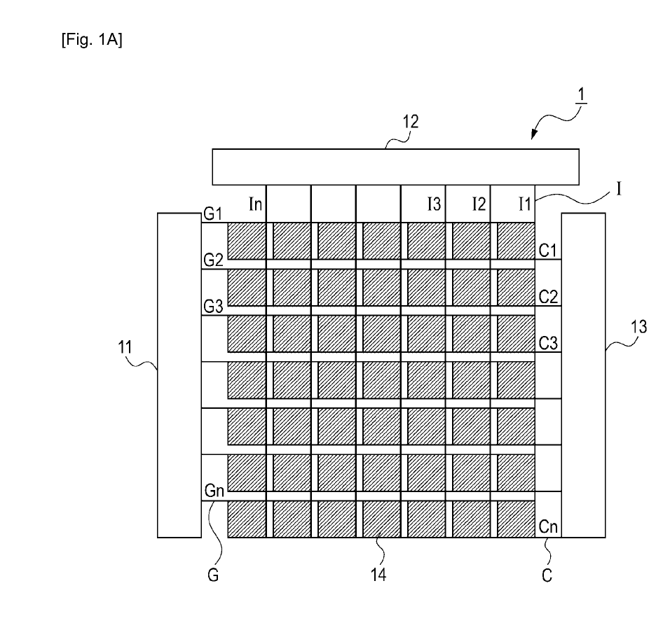

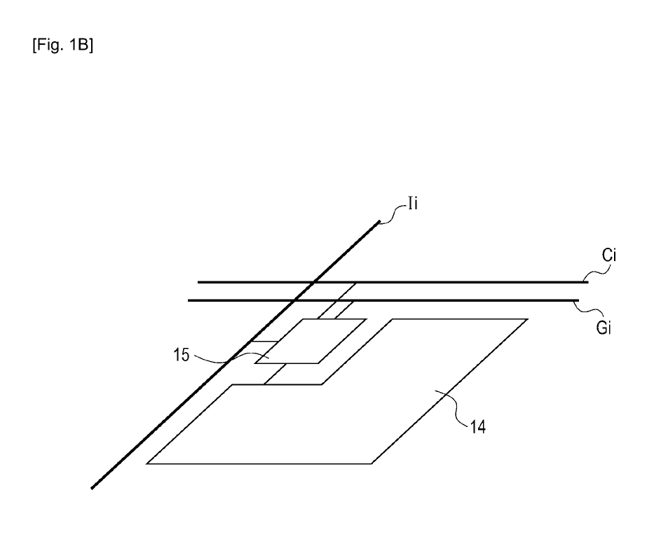

FIG. 1A is a schematic diagram illustrating an example of configuration of a display apparatus according to one embodiment. The display apparatus includes the organic light-emitting device of the present invention and a unit configured to supply electrical signals to the organic light-emitting device of the present invention.

FIG. 1B is a schematic diagram illustrating a pixel circuit connected to a pixel, and signal and electrical current supply lines connected to the pixel circuit.

The unit configured to supply electrical signals to the organic light-emitting device of the present invention includes a scan signal driver 11, a data signal driver 12, and an electrical current supply source 13 in FIG. 1A and a pixel circuit 15 in FIG. 1B.

A display apparatus 1 shown in FIG. 1A includes the scan signal driver 11, the data signal driver 12, and the electrical current supply source 13 which are respectively connected to gate selection lines G, data signal lines I, and electrical current supply lines C. Pixel circuits 15 are arranged at intersections of the gate selection lines G and the data signal lines I, as shown in FIG. 1B. One pixel 14 constituted by the organic light-emitting device of the present invention is provided for each corresponding pixel circuit 15. In other words, the pixel 14 is an organic light-emitting device. In the drawing, the organic light-emitting device is illustrated as the emission point. Upper electrodes of the organic light-emitting devices may be formed as a common upper electrode for all of the organic light-emitting devices. Of course, the upper electrodes of the respective organic light-emitting devices may be formed separately.

The scan signal driver 11 sequentially selects gate selection lines G1, G2, G3, . . . and Gn, in synchronization with which image signals are applied to the pixel circuits 15 via one of data signal lines I1, I2, I3, . . . and In from the data signal driver 12.

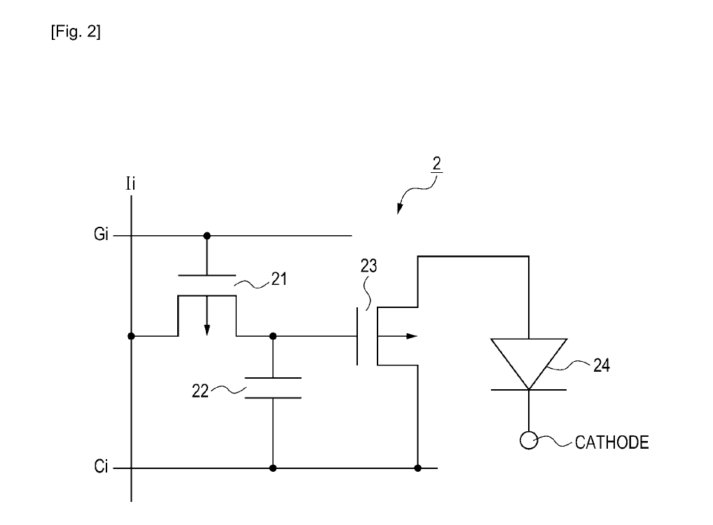

Next, operation of a pixel is described. FIG. 2 is a circuit diagram showing a circuit configuring one pixel in the display apparatus 1 shown in FIG. 1A. In FIG. 2, a second thin film transistor (TFT) 23 controls the electrical current for causing an organic light-emitting device 24 to emit light. In a pixel circuit 2 in FIG. 2, when a selection signal is applied to a gate selection line G1, the first TFT 21 is turned ON, an image signal Ii is supplied to a capacitor 22, and a gate voltage of the second TFT 23 is thereby determined. An electrical current is supplied to the organic light-emitting device 24 from an electrical current supply line Ci according to the gate voltage of the second TFT 23. Here, the gate potential of the second TFT 23 is retained in the capacitor 22 until the first TFT 21 is scanned and selected next. Accordingly, the electric current keeps flowing in the organic light-emitting device 24 until the next time scanning is performed. As a result, the organic light-emitting device 24 keeps emitting light during one frame period.

Although not shown in the drawings, the organic light-emitting device of the present invention can be used in a voltage-write display apparatus in which the voltage between the electrodes of the organic light-emitting device 24 is controlled by a thin film transistor.

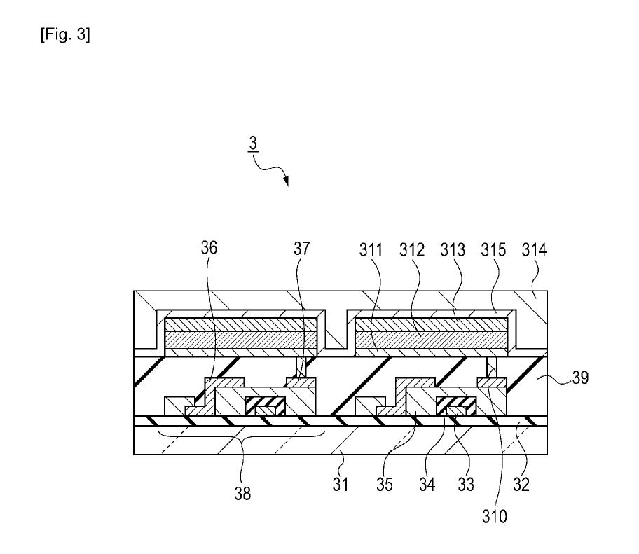

FIG. 3 is a schematic view showing one example of a cross-sectional structure of a TFT substrate used in the display apparatus shown in FIG. 1A. The detailed structure is described below by taking a method for making the TFT substrate as an example.

In making a display apparatus 3 shown in FIG. 3, first, a moisture-proof film 32 for protecting components (TFT or organic layer) formed thereon is formed on a substrate 31 composed of glass or the like by coating. Silicon oxide or a complex of silicon oxide and silicon nitride is used to form the moisture-proof film 32. Next, a metal film of Cr or the like is formed by sputtering and patterned into a particular circuit shape to form a gate electrode 33.

A film of silicon oxide or the like is formed by plasma-enhanced CVD or catalytic chemical vapor deposition (cat-CVD) and patterned to form a gate insulating film 34. A silicon film is formed by plasma-enhanced CVD or the like (annealing at a temperature of 290 degrees (Celsius) or more if necessary) and patterned according to a circuit shape to form a semiconductor layer 35.

A drain electrode 36 and a source electrode 37 are formed on the semiconductor layer 35 to form a TFT element 38. As a result, a circuit as shown in FIG. 2 is formed. Next, an insulating film 39 is formed on the TFT element 38. A contact hole (through hole) 310 is formed to connect a metal anode 311 for the organic light-emitting device to the source electrode 37.

A multilayer or single-layer organic layer 312 and a cathode 313 are sequentially layered on the anode 311. As a result, the display apparatus 3 is obtained. A first protective layer 314 and a second protective layer 315 may be provided to prevent deterioration of the organic light-emitting device. When the display apparatus using the organic light-emitting device of the present invention is driven, high-quality images can be displayed stably over a long time.

Note that the switching element of the display apparatus described above is not particularly limited, and the display apparatus can be applied even with a single crystal silicon substrate, a MIM device, an a-Si device, or the like.

An organic light-emitting display panel can be obtained by sequentially layering a single-layer or multilayer organic emission layer and a cathode layer on the ITO electrode. When the display panel using the organic compound of the present invention is driven, high-quality images can be displayed stably over a long time.

As for the direction in which the light is output from the device, either a bottom-emission structure (light is output from the substrate side) or a top-emission structure (light is output from the side opposite the substrate) is applicable.

### EXAMPLES

The present invention will now be described in further detail by using non-limiting examples.

### Production Example 1

### Method for Producing Example Compound 1-1

Example Compound 1-1, which is one example of the fused polycyclic compound represented by general formula [1] of the present invention, can be produced by the method described below, for example.

### (1) Synthesis of Intermediate Mixture 1

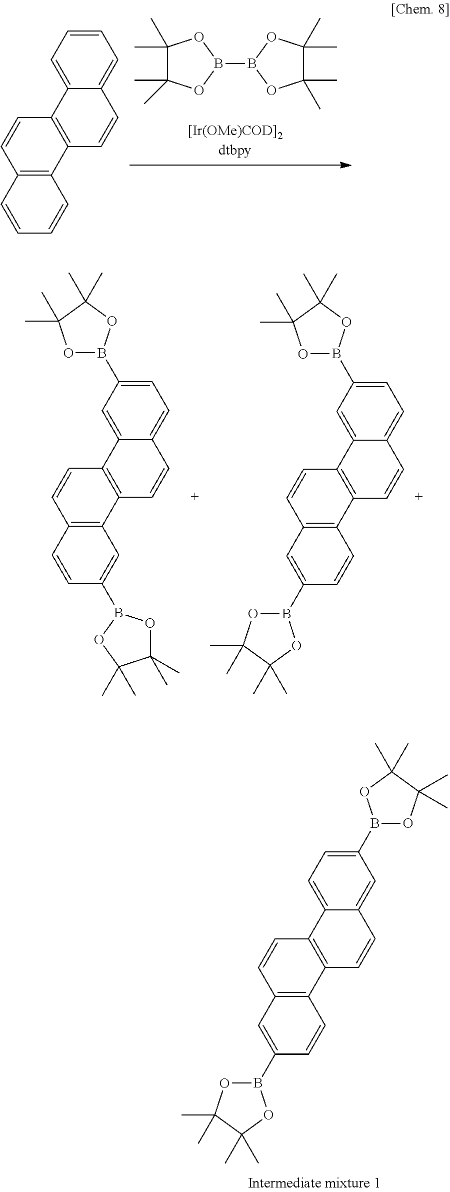

In a nitrogen atmosphere, the following compounds were mixed in cyclohexane (60 ml) and the resulting mixture was heated and stirred for 6 hours on a silicone oil bath heated to 80 degrees (Celsius):

chrysene: 3.00 g (13.1 mmol)

bis(pinacolato)diboron: 8.01 g (31.5 mmol)

[Ir(OMe)COD]₂: 0.250 g (0.377 mmol)

4,4′-di-tert-butyl-2,2′-bipyridine (dtbpy): 0.202 g (0.754 mmol)

After the mixture was cooled to room temperature, the reaction precipitates were filtered and the obtained solid was washed with heptane. Recrystallization was conducted in a chloroform/methanol system and the obtained white powder was vacuum-dried at 80 degrees (Celsius). As a result, 4.23 g (yield: 67%) of intermediate mixture 1 was obtained.

### (2) Synthesis of Intermediate Mixture 2

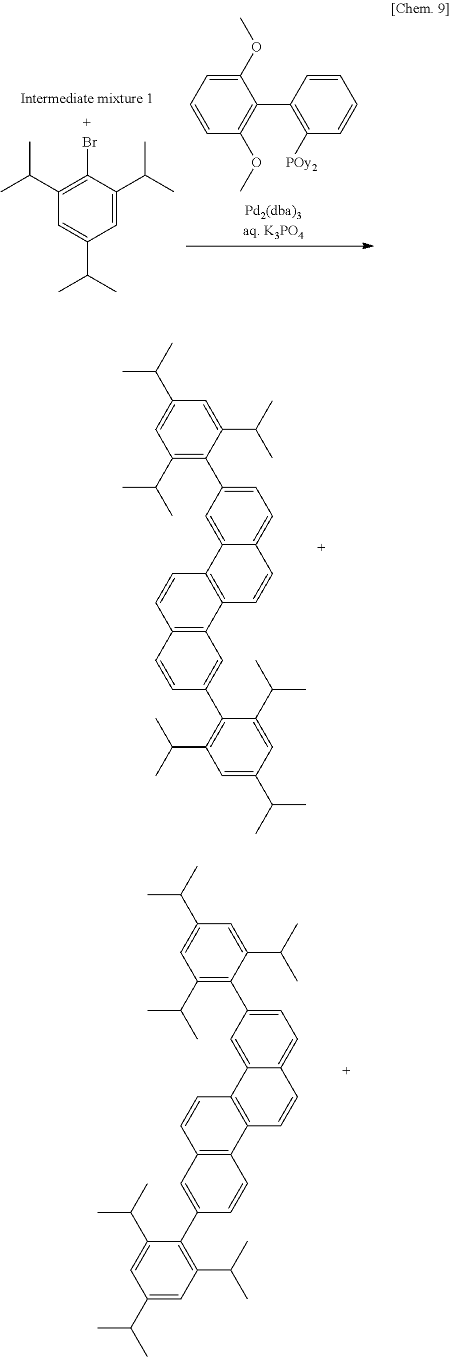

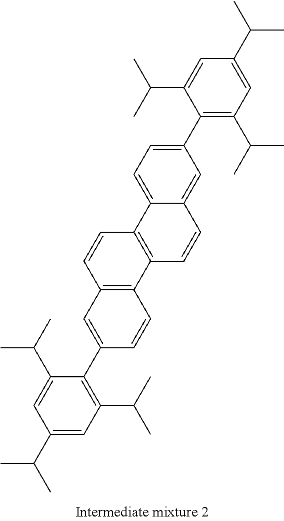

In a nitrogen atmosphere, the following compounds were mixed in toluene (16 ml). An aqueous solution prepared by dissolving 4.30 g (19.1 mmol) of potassium phosphate in 9 ml of distilled water was added thereto, and the resulting mixture was heated and stirred for 3 hours on a silicone oil bath heated to 90 degrees (Celsius).

intermediate mixture 1: 2.30 g (4.79 mmol)

2,4,6-triisopropylbromobenzene: 4.10 g (14.5 mmol)

2-dicyclohexylphosphino-2′,6′-dimethoxybiphenyl: 0.433 g (1.05 mmol)

Pd₂ dba₃: 0.219 g (0.240 mmol)

After the mixture was cooled to room temperature, water, toluene, and ethyl acetate were added to separate the organic layer. The water layer was extracted (twice) with a mixed solvent of toluene and ethyl acetate and added to the organic layer solution initially separated. The organic layer was washed with saturated saline and dried with sodium sulfate. The solvent was distilled away and the residue was purified by silica gel column chromatography (mobile phase: toluene:heptane=1:3). Vacuum drying was performed at 80 degrees (Celsius) and 1.52 g (yield: 50%) of intermediate mixture 2 was obtained as a result.

### (3) Synthesis of Intermediate Mixture 3

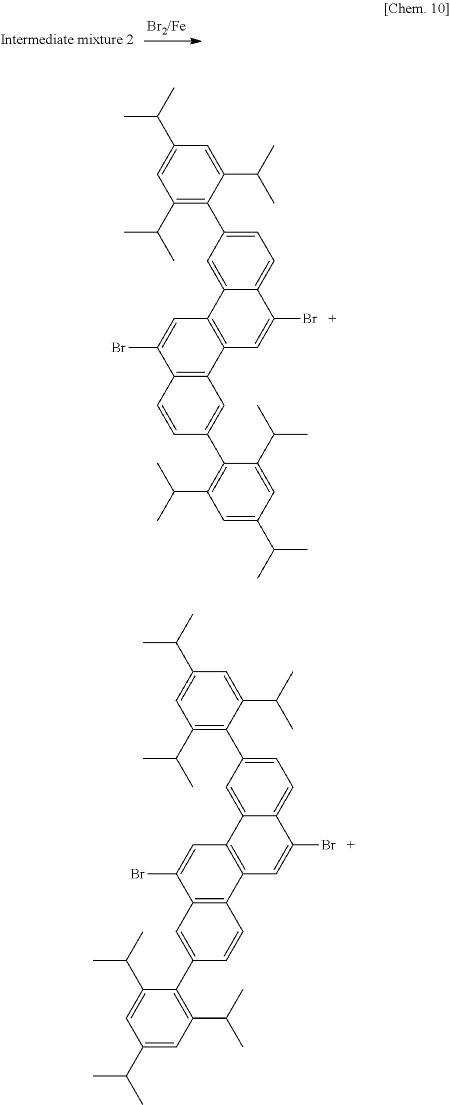

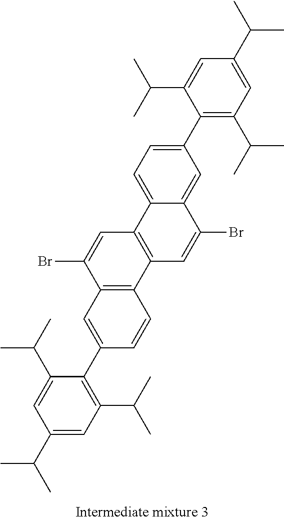

In a nitrogen atmosphere, intermediate mixture 2 (0.900 g, 1.42 mmol) was dissolved in dichloromethane (5 ml), 0.100 g of iron powder was added thereto, and the resulting mixture was ice-cooled to 0 degrees (Celsius). Subsequently, 7.3 ml of a 2 vol % dichloromethane solution of bromine was added thereto dropwise, and the resulting reaction solution was returned to room temperature and stirred for 2 hours. Chloroform and a saturated aqueous sodium thiosulfate solution were added thereto and the resulting mixture was stirred until the color of bromine was vanished. The organic layer was separated, washed with saturated saline, and dried with sodium sulfate. The solvent was distilled away and the residue was recrystallized in a chloroform/methanol system. The obtained white powder was vacuum-dried at 80 degrees (Celsius). As a result, 1.07 g (yield: 95%) of intermediate mixture 3 was obtained.

### (4) Synthesis of Intermediate 4

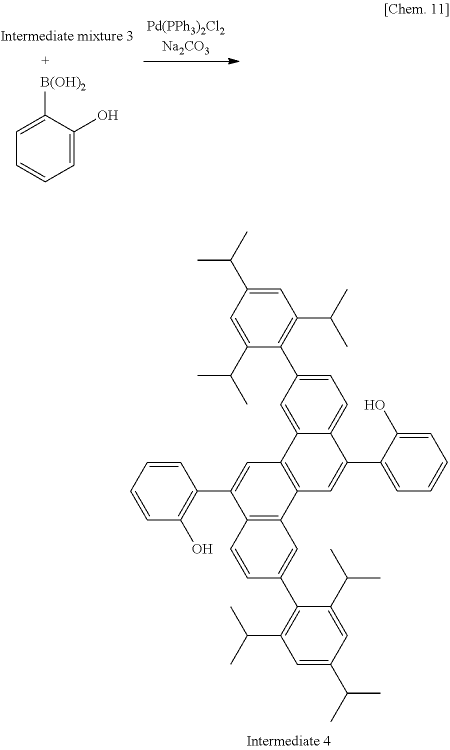

In a nitrogen atmosphere, the following compounds were suspended in a mixed solvent of tetrahydrofuran (10 ml) and distilled water (0.8 ml) and the suspension was heated and stirred for 5 hours on a silicone oil bath heated to 80 degrees (Celsius).

intermediate mixture 3: 1.07 g (1.35 mmol)

2-hydroxyphenylboronic acid: 0.560 g (4.06 mmol)

Pd(PPh₃)₂Cl₂: 0.0948 g (0.135 mmol), sodium carbonate: 0.859 g (8.10 mmol)

After the mixture was cooled to room temperature, water, and toluene, ethyl acetate were added to separate the organic layer. The water layer was extracted (twice) with a mixed solvent of toluene and ethyl acetate and added to the organic layer solution initially separated. The organic layer was washed with saturated saline and dried with sodium sulfate. The solvent was distilled away and the residue was purified by silica gel column chromatography (mobile phase: chloroform:heptane=4:1). Vacuum drying was performed at 100 degrees (Celsius) and 0.255 g (yield: 23%) of intermediate 4 was obtained as a result.

### (5) Synthesis of Intermediate 5

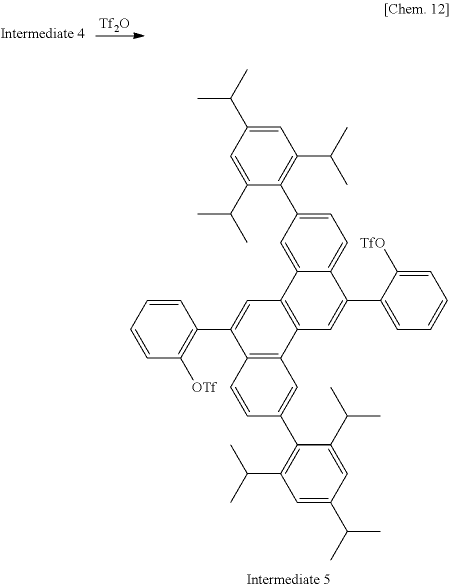

In a nitrogen atmosphere, intermediate 4 (0.255 g, 0.312 mmol) was dissolved in pyridine (5 ml) and the resulting solution was ice-cooled to 0 degrees (Celsius).

Subsequently, 0.155 ml of trifluoromethanesulfonic anhydride was added dropwise and the reaction solution was returned to room temperature and stirred for 2 hours. The solvent was distilled away and the residue was washed with methanol and purified by silica gel column chromatography (mobile phase:chloroform:heptane=1:2). Vacuum drying was performed at 100 degrees (Celsius) and 0.240 g (yield: 71%) of intermediate 5 was obtained as a result.

### (6) Synthesis of Example Compound 1-1

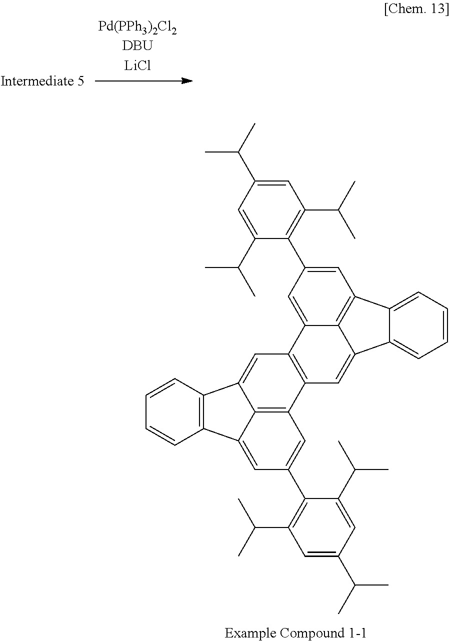

In a nitrogen atmosphere, the following compounds were mixed in N,N-dimethylformamide (10 ml) and the resulting mixture was heated and stirred for 10 hours on a silicone oil bath heated to 140 degrees (Celsius):

intermediate 5: 0.200 g (0.185 mmol)

1,8-diazabicyclo[5.4.0]-7-undecene (DBU): 0.113 g (0.740 mmol)

Pd(PPh₃)₂Cl₂: 0.0260 g (0.37 mmol), lithium chloride: 0.047 g (1.11 mmol)

After the mixture was cooled to room temperature, water, toluene, and ethyl acetate were added to separate the organic layer. The water layer was extracted (twice) with a mixed solvent of toluene and ethyl acetate and added to the organic layer solution initially separated. The organic layer was washed with saturated saline and dried with sodium sulfate. The solvent was distilled away and the residue was purified by silica gel column chromatography (mobile phase: chloroform:heptane=1:3). Vacuum drying was conducted at 120 degrees (Celsius), followed by sublimation purification. As a result, 0.032 g (yield: 22%) of Example Compound 1-1 was obtained as a yellow solid.

Matrix-assisted laser desorption/ionization time-of-flight mass spectroscopy (MALDI-TOF MS) confirmed M⁺ of this compound at 780.5.

The structure of this compound was also confirmed by ¹H-NMR.

¹H-NMR (CDCl₃, 600 MHz) d (ppm): 9.14 (1H, s), 8.54 (1H, s), 8.08 (1H, m), 7.93 (2H, m), 7.45 (2H, m), 7.21 (2H, s), 3.05 (1H, m), 2.81 (2H, m), 1.40 (3H, s), 1.39 (3H, s), 1.18 (3H, s), 1.17 (3H, s), 1.16 (3H, s), 1.15 (3H,s)

The fluorescent spectrum of a toluene solution containing Example Compound 1-1 at a concentration of 1×10⁻⁵ mol/l was measured with F-4500 produced by Hitachi Ltd., at an excitation wavelength of 370 nm. The fluorescent peak wavelength is shown in Table 1 above.

A tetrahydrofuran solution containing Example Compound 1-1 at a concentration of 0.1 wt % was also prepared. The solution was dropped onto a glass plate and spin-coating was conducted first for 10 seconds at 500 rpm and then for 40 seconds at 1000 rpm to form a film.

The fluorescent spectrum of this organic film was measured with F-4500 produced by Hitachi Ltd., at an excitation wavelength of 370 nm. The fluorescent peak wavelength is shown in Table 2 above.

### Comparative Example 1

### Method for producing C-1

C-1 can be synthesized as in sections (4), (5), and (6) in Production Example 1 except that 6,12-dibromochrysene was used instead of intermediate mixture 3 in (4) of Production Example 1.

The fluorescent spectra of the toluene solution of C-1 and the spin-coated film of C-1 were measured as in Production Example 1. The fluorescent peak wavelengths are shown in Tables 1 and 2 above.

### Comparative Example 2

### Method for producing C-2

C-2 can be synthesized through the following scheme:

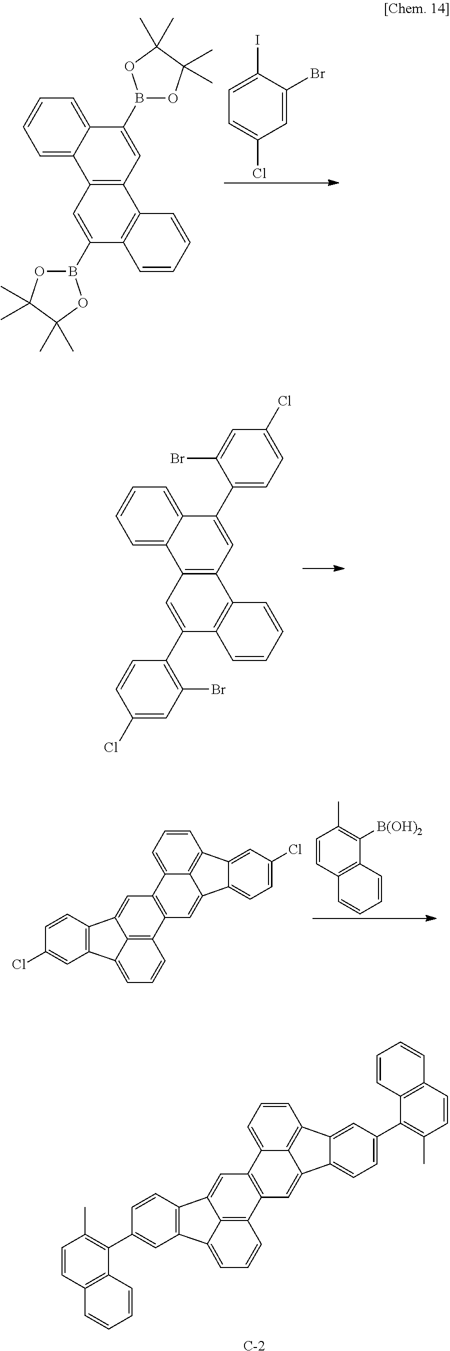

The fluorescent spectra of the toluene solution of C-2 and the spin-coated film of C-2 were measured as in Production Example 1. The fluorescent peak wavelengths are shown in Tables 1 and 2 above.

### Comparative Example 3

### Method for producing C-3

C-3 can be synthesized through the following scheme:

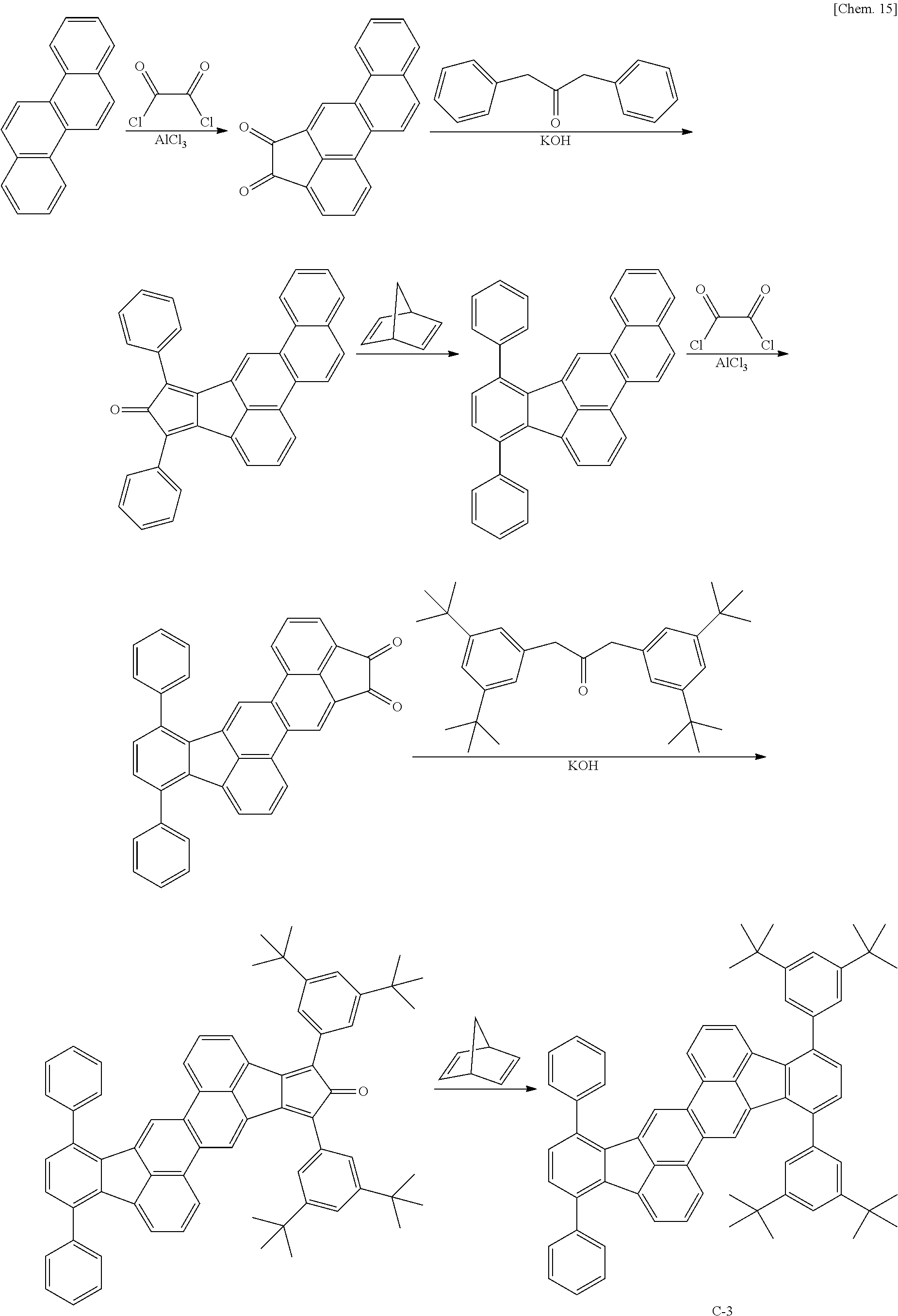

The fluorescent spectra of the toluene solution of C-3 and the spin-coated film of C-3 were measured as in Production Example 1. The fluorescent peak wavelengths are shown in Tables 1 and 2 above.

### Example 1

An organic light-emitting device was produced by the following method.

An ITO film 120 nm in thickness and serving as the anode was sputter-deposited on a glass substrate and this glass substrate was used as a transparent conductive supporting substrate. The substrate was sequentially ultrasonically washed with acetone and isopropyl alcohol (IPA) and washed with pure water, followed by drying. The substrate was further washed with UV/ozone so that it can be used as the transparent conductive supporting substrate. Compound A represented by the structural formula below was used as the hole transport material and a chloroform solution of compound A at a concentration of 0.1 wt % was prepared.

The solution was dropped onto the ITO electrode and spin-coating was conducted first for 10 seconds at 500 rpm and then for 40 seconds at 1000 rpm to form a film. Then the film was dried in a vacuum oven at 80 degrees (Celsius) for 10 minutes to completely eliminate the solvent in the thin film and to thereby form a hole transport layer.

Example Compound 1-1 and compound B below were co-deposited (weight ratio=5:95) on the hole transport layer to provide an emission layer having a thickness of 30 nm The degree of vacuum during deposition was 1.0×10⁻⁴ Pa and the deposition rate was 0.1 nm/sec or more and 0.2 nm/sec or less.

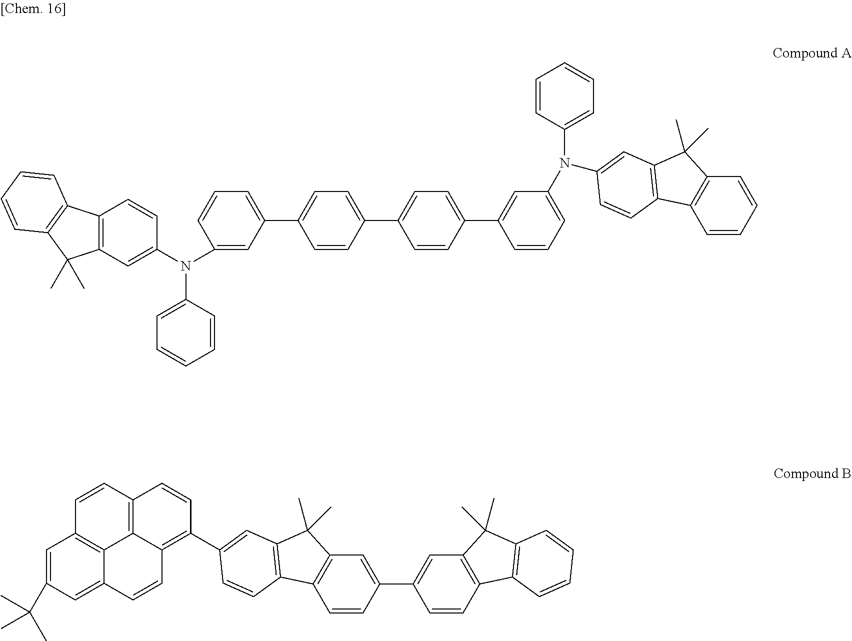

As an electron transport layer, 2,9-bis[2-(9,9′-dimethylfluorenyl)]-1,10-phenanthroline was vacuum vapor-deposited to form a film having a thickness of 30 nm. The degree of vacuum during the deposition was 1.0×10⁻⁴ Pa and the deposition rate was 0.1 nm/sec or more and 0.2 nm/sec or less.

Next, lithium fluoride (LiF) was vacuum vapor-deposited on the organic layer to a thickness of 0.5 nm, and an aluminum film serving as an electron injection electrode and having a thickness of 100 nm was formed thereon by vacuum vapor deposition to produce an organic light-emitting device. The degree of vacuum during the deposition was 1.0×10⁻⁴ Pa and the deposition rates were 0.01 nm/sec for lithium fluoride and 0.5 nm/sec or more and 1.0 nm/sec or less for aluminum.

The obtained organic light-emitting device was covered with a protective glass plate in a dry air atmosphere to prevent device deterioration by moisture adsorption and sealed with an acryl resin adhesive.

The characteristics of the obtained organic light-emitting device were measured and evaluated. In particular, the current-voltage characteristic of the device was measured with a pA meter 4140B produced by Hewlett-Packard Company and the luminance of emission was measured with BM7 produced by Topcon Corporation. Satisfactory blue emission having a luminance of 403 cd/m² was observed at an application voltage of 4.0 V. In a nitrogen atmosphere, voltage was applied on this device for 100 hours. Continuation of satisfactory emission was confirmed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-094100, filed Apr. 8, 2009, which is hereby incorporated by reference herein in its entirety.

### REFERENCE SIGNS LIST

1 Display apparatus
11 Scan signal driver
12 Data signal driver
13 Electrical current supply line
14 Pixel

1. A fused polycyclic compound represented by general formula [1]: 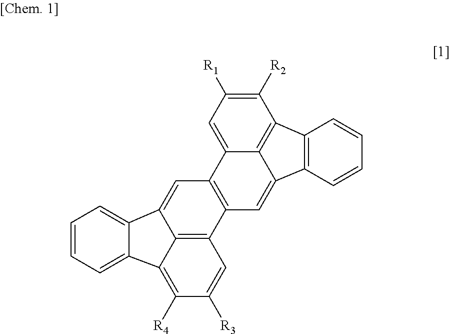
(In general formula [1], at least one of R₁ to R₄ is a group selected from a substituted or unsubstituted aryl group and a substituted or unsubstituted heterocyclic group, and R₁ to R₄ may be the same as or different from each other.)

2. The fused polycyclic compound according to claim 1, wherein, in general formula [1], R₂ and R₄ are each a hydrogen atom; and at least one of R₁ and R₃ is a group selected from a substituted or unsubstituted aryl group and a substituted or unsubstituted heterocyclic group and R₁ and R₃ may be the same as or different from each other.

3. An organic light-emitting device comprising:
an anode;
a cathode; and
an organic compound layer interposed between the anode and the cathode,
wherein the organic compound layer at least contains the fused polycyclic compound according to claim 1.

4. A display apparatus comprising:
the organic light-emitting device according to claim 3; and
a unit configured to supply electrical signals to the organic light-emitting device.

5. An image capturing apparatus comprising:
the organic light-emitting device according to claim 3; and
a photo detector,
wherein a finder comprises the organic light-emitting device.

6. A printer comprising:
the organic light-emitting device according to claim 3, the organic light emitting device being arranged in an array;
a light source having a unit that can be addressed independently; and
a photosensitive drum.
